(19) United States
(12) Patent Application Publication
(10) Pub. No.: US 2026/0143882 A1
(43) Pub. Date: May 21, 2026

(54) LIGHT-EMITTING DIODE DISPLAY DEVICE

(71) Applicant: LG Display Co., Ltd., Seoul (KR)

(72) Inventors: Tae-Yong KIM, Paju-si (KR); Byung-Hyun LEE, Paju-si (KR); Dae-Young SEO, Paju-si (KR); Su-Min LEE, Paju-si (KR)

(73) Assignee: LG Display Co., Ltd., Seoul (KR)

(21) Appl. No.: 19/188,735

(22) Filed: Apr. 24, 2025

(30) Foreign Application Priority Data
Nov. 18, 2024 (KR) 10-2024-0164119

(51) Int. Cl. H10H 29/34; H10H 29/39; H10H 29/80; H10H 29/85

(52) U.S. Cl. CPC H10H 29/345; H10H 29/39; H10H 29/842; H10H 29/8517

(57) ABSTRACT

A light-emitting diode display device is provided with a substrate including a first sub-pixel and a second sub-pixel; a first light-emitting element provided in the first sub-pixel over the substrate; and a second light-emitting element provided in the second sub-pixel over the substrate, wherein the second light-emitting element includes a first electrode, a light-emitting layer, and a second electrode, and wherein the light-emitting layer is further provided in the first sub-pixel and overlaps the first light-emitting element.

### CROSS-REFERENCE TO RELATED APPLICATION

The present application claims priority to Korean Patent Application No. 10-2024-0164119 filed in the Republic of Korea on November 18, 2024, the entire contents of which are hereby expressly incorporated by reference into the present application.

### BACKGROUND

### Technical Field

The present disclosure relates to a display device, and more particularly, to a light-emitting diode display device.

### Description of the Related Art

As the information society progresses, a demand for different types of display devices increases, and flat panel display devices (FPD) such as liquid crystal display devices and light-emitting diode display devices have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device can offer various advantages and improved properties. For instance, compared to the liquid crystal display device, because it is self-luminous, the light-emitting diode display device has a wide viewing angle, and since a backlight unit is not required, the light-emitting diode display device has an ultra-thin thickness and light weight. In addition, the light-emitting diode display device is also advantageous in power consumption.

The light-emitting diode display device can include a plurality of pixels, each of which includes a plurality of sub-pixels emitting light of different colors, for example, red, green, and blue sub-pixels and display various color images by selectively emitting light-emitting elements of the red, green, and blue sub-pixels.

### BRIEF SUMMARY

The light-emitting diode display device can include an organic light-emitting diode or an inorganic light-emitting diode as the light-emitting element. For example, the light-emitting diode display device may include red, green, and blue organic light-emitting diodes or, alternatively, red, green, and blue inorganic light-emitting diodes. However, blue organic light-emitting diode generally exhibit relatively low quantum efficiency, resulting in reduced luminous efficiency. Consequently, the blue organic light-emitting diode tend to have lower brightness and shorter lifespans, which can negatively impact the overall lifetime of the display device. In addition, the brightness of the organic light-emitting diode can vary depending on the aperture ratio, and the organic light-emitting diodes are often limited in their ability to expand the emission area, which constrains improvement in aperture ratio.

In view of these challenges, the inventors have developed various embodiments that address one or more of the limitations in the related art, including the aforementioned issues. Specifically, the various embodiments of the present disclosure are directed to a light-emitting diode display device configured to substantially overcome the drawbacks associated with prior technologies.

An aspect of the present disclosure is to provide a light-emitting diode display device with improved luminous efficiency, increased brightness, extended display lifetime, and reduced power consumption. Additional technical benefits may include a compact and space-efficient layout, achieved through the use of a shared organic light-emitting layer and a recessed structure that simplifies electrode connections and enables efficient use of space within each sub-pixel. This contributes to the development of thinner, lighter, and more efficient displays. Furthermore, the recessed structure facilitates natural separation of light-emitting layers and enables electrical contact without the need for additional patterning steps, thereby enhancing manufacturing efficiency. As is well understood, a reduction in the number of layers and photomasks can lead to a streamlined fabrication process and potential cost savings.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a light-emitting diode display device is provided with a substrate including a first sub-pixel and a second sub-pixel; a first light-emitting element provided in the first sub-pixel over the substrate; and a second light-emitting element provided in the second sub-pixel over the substrate, wherein the second light-emitting element includes a first electrode, a light-emitting layer, and a second electrode, and wherein the light-emitting layer is further provided in the first sub-pixel and overlaps the first light-emitting element.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a schematic plan view of a light-emitting diode display device according to an embodiment of the present disclosure;

FIG. 2 is an example of an equivalent circuit diagram of one sub-pixel of a light-emitting diode display device according to an embodiment of the present disclosure;

FIG. 3 is a schematic cross-sectional view of a light-emitting diode display device according to an embodiment of the present disclosure;

FIG. 4 is a schematic plan view of a first sub-pixel of a light-emitting diode display device according to the embodiment of the present disclosure;

FIG. 5 is a schematic cross-sectional view of a first sub-pixel of a light-emitting diode display device according to the embodiment of the present disclosure corresponding to line I-I′ of FIG. 1; and

FIG. 6 is a schematic cross-sectional view of a second sub-pixel of the light-emitting diode display device according to the embodiment of the present disclosure corresponding to line II-II′ of FIG. 1.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms "connected" and "coupled" are intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and “in contact” should be interpreted in the same manner. For example, the term “in contact with,” as used herein, encompasses both “indirect contact” and “direct contact.” Accordingly, when the phrase “A is in contact with B” is used, it implies that other components may be present between A and B, unless explicitly specified as “A is in direct contact with B.”

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

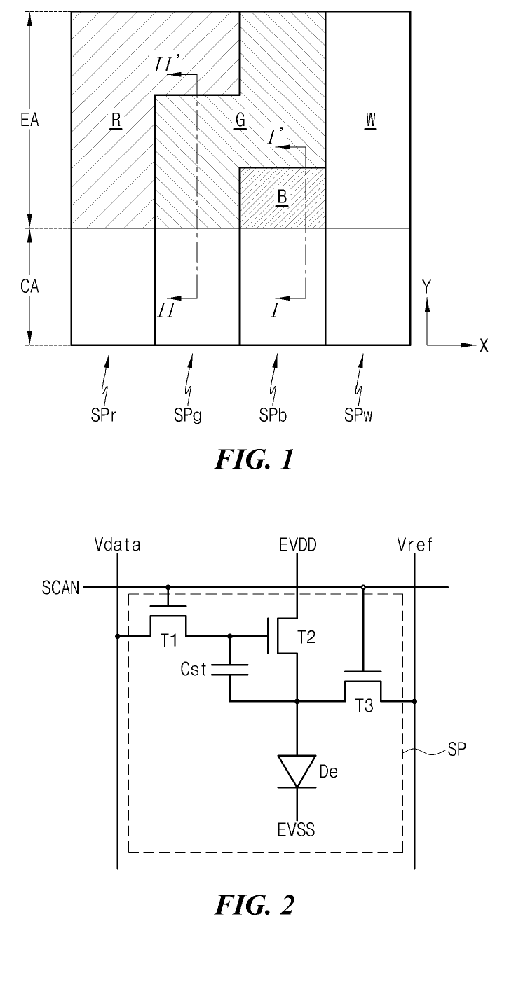

FIG. 1 is a schematic plan view of a light-emitting diode display device according to an embodiment of the present disclosure and shows one pixel.

In FIG. 1, one pixel of the light-emitting diode display device according to the embodiment of the present disclosure can include a plurality of sub-pixels SPr, SPg, SPb, SPw. The plurality of sub-pixels SPr, SPg, SPb, SPw can be substantially arranged in a first direction X.

For example, the pixel can include four sub-pixels, that is, red, green, blue, and white sub-pixels SPr, SPg, SPb, and SPw. However, embodiments of the present disclosure are not limited thereto. In other embodiments, one pixel can include three sub-pixels, for example, red, green, and blue sub-pixels.

Each of the red, green, blue, and white sub-pixels SPr, SPg, SPb, and SPw can include an emission area EA and a circuit area CA. The emission area EA and the circuit area CA can be disposed adjacent to each other in a second direction Y crossing the first direction X. A light-emitting element can be provided in the emission area EA, and at least one transistor and at least one capacitor can be provided in the circuit area CA.

The red, green, blue, and white sub-pixels SPr, SPg, SPb, and SPw can have different areas. Specifically, the emission areas EA of the red, green, blue, and white sub-pixels SPr, SPg, SPb, and SPw can have different areas, and the circuit areas CA of the red, green, blue, and white sub-pixels SPr, SPg, SPb, and SPw can have the same area.

For example, the areas of the red and green sub-pixels SPr and SPg can be greater than the area of the blue sub-pixel SPb. In addition, the area of the white sub-pixel SPw can be smaller than the areas of the red and green sub-pixels SPr and SPg and greater than the area of the blue sub-pixel SPb.

Here, the areas of the red and green sub-pixels SPr and SPg can be the same. However, embodiments of the present disclosure are not limited thereto. In other embodiments, the areas of the red and green sub-pixels SPr and SPg can be different.

The red and green sub-pixels SPr and SPg can have different shapes. For example, the red sub-pixel SPr can have a substantially L-like shape including a portion extending in the first direction X and a portion extending in the second direction Y. The green sub-pixel SPg can have a substantially Z-like shape including a portion extending in the first direction X and two portions extending in the second direction Y.

In addition, the blue sub-pixel SPb and the white sub-pixel SPw can have rectangular shapes, and a length of the white sub-pixel SPw can be longer than a length of the blue sub-pixel SPb in the second direction Y.

A first light-emitting element can be provided in the emission area EA of the blue sub-pixel SPb, and a second light-emitting element can be provided in the emission area EA of each of the red, green, and white sub-pixels SPr, SPg, and SPw. The first light-emitting element can emit blue light, and the second light-emitting element can emit white light. Here, the first light-emitting element can be an inorganic light-emitting diode, and the second light-emitting element can be an organic light-emitting diode.

Since the inorganic light-emitting diode has a relatively small size compared to the organic light-emitting diode, in the light-emitting diode display device according to the embodiment of the present disclosure, the area of the blue sub-pixel SPb provided with the inorganic light-emitting diode can be decreased, and the areas of the red and green sub-pixels SPr and SPg provided with the organic light-emitting diode can be increased to correspond to the decreased area of the blue sub-pixel SPb.

Accordingly, the aperture ratio of the organic light-emitting diode can be increased, so that the brightness can be improved and the power consumption can be reduced.

The sub-pixels SPr, SPg, SPb, and SPw of the light-emitting diode display device according to the embodiment of the present disclosure can have substantially the same configuration except for the light-emitting elements provided in the emission areas EA, and the configuration of the sub-pixels SPr, SPg, SPb, and SPw will be described in detail with reference to accompanying drawings.

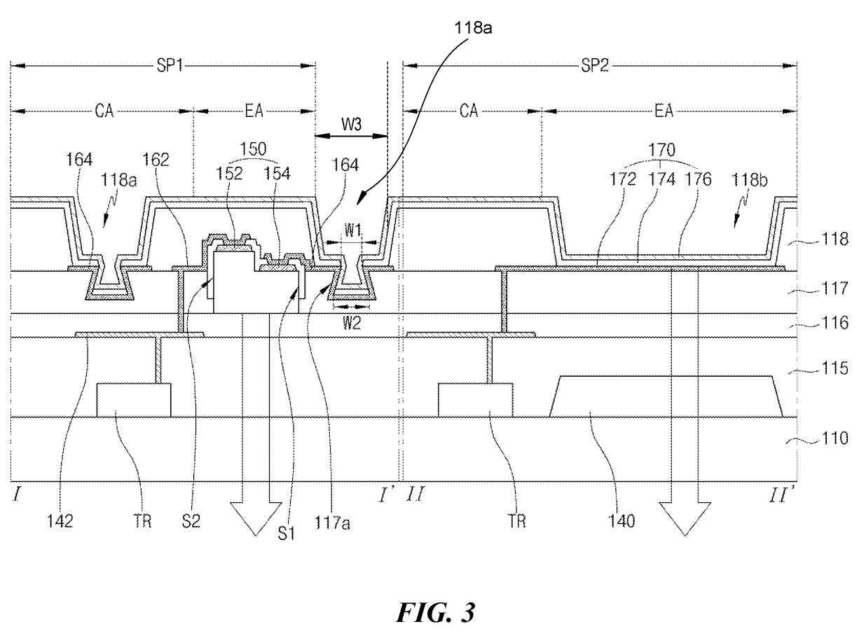

FIG. 2 is an example of an equivalent circuit diagram of one sub-pixel of a light-emitting diode display device according to an embodiment of the present disclosure.

In FIG. 2, the sub-pixel SP of the light-emitting diode display device according to the embodiment of the present disclosure can include a switching transistor T1, a driving transistor T2, and a sensing transistor T3, a storage capacitor Cst, and a light-emitting diode De.

As described above, when the sub-pixel SP of FIG. 2 is the blue sub-pixel SPb of FIG. 1, the light-emitting diode De can be an inorganic light-emitting diode, and when the sub-pixel SP of FIG. 2 is one of the red, green, and white sub-pixels SPr, SPg, and SPw of FIG. 1, the light-emitting diode De can be an organic light-emitting diode.

The switching transistor T1, the driving transistor T2, and the sensing transistor T3 can be n-type transistors. However, embodiments of the present disclosure are not limited thereto. Alternatively, the switching transistor T1, the driving transistor T2, and the sensing transistor T3 can be p-type transistors or other types of transistors.

Specifically, a gate line supplying a scan signal (or gate signal) SCAN and a data line supplying a data signal Vdata can cross each other, and the switching transistor T1 can be disposed at a crossing point of the gate line and the data line. A gate of the switching transistor T1 can be connected to the gate line to receive the gate signal SCAN, and a drain of the switching transistor T1 can be connected to the data line to receive the data signal Vdata.

In addition, a gate of the driving transistor T2 can be connected to a source of the switching transistor T1 and a first capacitor electrode of the storage capacitor Cst. A drain of the driving transistor T2 can be connected to a high potential line supplying a high potential voltage EVDD, and a source of the driving transistor T2 can be connected to an anode of the light-emitting diode De, a second capacitor electrode of the storage capacitor Cst, and a source of the sensing transistor T3.

A gate of the sensing transistor T3 can be connected to the gate line, and a drain of the sensing transistor T3 can be connected to a reference line supplying a reference voltage Vref. Alternatively, the gate of the sensing transistor T3 can be connected to a separate sensing line.

Here, the source and drain locations of each of the transistors T1, T2, and T3 are not limited thereto, and the locations can be interchanged or varied.

Meanwhile, a cathode of the light-emitting diode De can be connected to a low potential line supplying a low potential voltage EVSS. Alternatively, the cathode of the light-emitting diode De can be connected to a ground voltage.

During an emission period of one frame, the switching transistor T1 can be switched according to the gate signal SCAN transmitted through the gate line to thereby provide the gate of the driving transistor T2 with the data signal Vdata transmitted through the data line. The driving transistor T2 can be switched according to the data signal Vdata to thereby control a current of the light-emitting diode De. In this case, the storage capacitor Cst can maintain charges corresponding to the data signal Vdata for one frame. Accordingly, even if the switching transistor T1 is turned off, the storage capacitor Cst can allow the amount of the current flowing through the light-emitting diode De to be constant and the gray level shown by the light-emitting diode De to be maintained until a next frame.

In addition, one frame can further include a sensing period. During the sensing period, the sensing transistor T3 can be switched according to the gate signal SCAN transmitted through the gate line to thereby provide the source of the driving transistor T2 with the reference voltage Vref. The sensing transistor T3 can detect the voltage change of the source of the driving transistor T2 through the reference line and can calculate the threshold voltage Vth of the driving transistor T2 by comparing the amount of the voltage change with a determination range. Accordingly, by calculating the threshold voltage Vth in real time and compensating for the image data, it is possible to compensate for the change in the characteristics of the driving transistor T2 and prevent image degradation.

However, the configuration of the sub-pixel of the light-emitting diode display device according to the embodiment of the present disclosure is not limited thereto. In some embodiments, the sensing transistor T3 can be omitted. In addition, the number and connection relationship of the transistors, the storage capacitor and/or the light-emitting diode can vary.

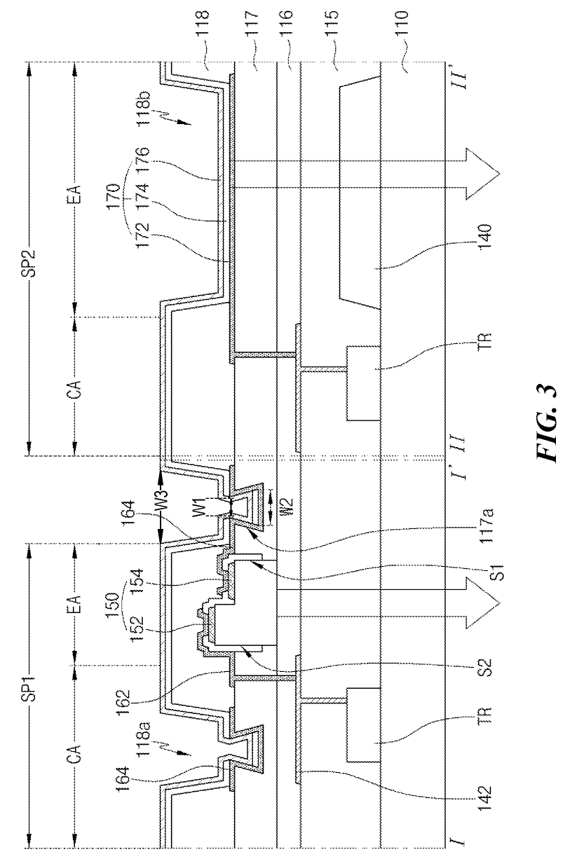

FIG. 3 is a schematic cross-sectional view of a light-emitting diode display device according to an embodiment of the present disclosure and shows a cross-section corresponding to line I-I′ and line II-II′ of FIG. 1.

In FIG. 3, a first sub-pixel SP1 and a second sub-pixel SP2 can be provided over a substrate 110. Each of the first sub-pixel SP1 and the second sub-pixel SP2 can include an emission area EA and a circuit area CA.

Here, the first sub-pixel SP1 can be the blue sub-pixel SPb of FIG. 1, and the second sub-pixel SP2 can be one of the red, green, and white sub-pixels SPr, SPg, and SPw of FIG. 1. For example, the second sub-pixel SP2 can be the green sub-pixel SPg of FIG. 1.

At least one thin film transistor TR can be provided over the substrate 110. The at least one thin film transistor TR can be disposed in the circuit area CA of each of the first and second sub-pixels SP1 and SP2.

In addition, a color filter layer 140 can be provided in the emission area EA of the second sub-pixel SP2 over the substrate 110, and a color filter layer may not be provided in the emission area EA of the first sub-pixel SP1. Here, when the second sub-pixel SP2 is the white sub-pixel SPw, the color filter layer 140 can be omitted.

A planarization layer 115 can be provided over the thin film transistor TR and the color filter layer 140. A pixel electrode 142 can be provided in the circuit area CA over the planarization layer 115. The pixel electrode 142 can be electrically connected to the thin film transistor TR.

Next, an adhesive layer 116 can be provided over the pixel electrode 142. A first light-emitting element 150 can be provided in the emission area EA of the first sub-pixel SP1 over the adhesive layer 116. The first light-emitting element 150 can be an inorganic light-emitting diode and include a first element electrode 152 and a second element electrode 154 at a top surface thereof.

An overcoat layer 117 can be provided over the adhesive layer 116 provided with the first light-emitting element 150 thereon. The overcoat layer 117 can have a recessed portion 117a, which is spaced apart from the first light-emitting element 150 and surrounds at least one side of the first light-emitting element 150. A side wall of the recessed portion 117a can have a reverse inclination with respect to the substrate 110.

A first connection electrode 162, a second connection electrode 164, and a first electrode 172 can be provided over the overcoat layer 117. The first connection electrode 162 and the second connection electrode 164 can be disposed in the first sub-pixel SP1, and the first electrode 172 can be disposed in the second sub-pixel SP2.

Here, each of the first connection electrode 162 and the first electrode 172 can be in contact with the pixel electrode 142 through a contact hole provided in the adhesive layer 116 and the overcoat layer 117.

In the second sub-pixel SP2, the first electrode 172 can be disposed in the emission area EA and partially in the circuit area CA and can overlap the color filter layer 140.

Meanwhile, in the first sub-pixel SP1, the first connection electrode 162 can be in contact with the first element electrode 152 of the first light-emitting element 150, and the second connection electrode 164 can be in contact with the second element electrode 154 of the first light-emitting element 150.

In addition, the first connection electrode 162 can be spaced apart from the recessed portion 117a, and the second connection electrode 164 can overlap the recessed portion 117a (both from a plan view and a cross-sectional view). The second connection electrode 164 can be in contact with a top surface of the overcoat layer 117 and can also be provided on a side surface and a bottom surface of the overcoat layer 117 corresponding to the recessed portion 117a.

A bank layer 118 can be provided over the first connection electrode 162, the second connection electrode 164, and the first electrode 172. The bank layer 118 can expose the second connection electrode 164 and the first electrode 172.

More specifically, in the first sub-pixel SP1, the bank layer 118 can cover the first light-emitting element 150 and the first connection electrode 162 and can have a first opening 118a that exposes the second connection electrode 164 corresponding to the recessed portion 117a.

Meanwhile, in the second sub-pixel SP2, the bank layer 118 can have a second opening 118b that exposes the first electrode 172 corresponding to the emission area EA. The second opening 118b can be provided to correspond to the color filter layer 140. The color filter layer 140 may not be provided in the first sub-pixel SP1, so that the second opening 118b may not be provided in the first sub-pixel SP1.

A light-emitting layer 174 and a second electrode 176 can be sequentially provided on the bank layer 118 and disposed substantially all over the substrate 110.

In the emission area EA of the second sub-pixel SP2, the first electrode 172, the light-emitting layer 174, and the second electrode 176 can constitute a second light-emitting element 170. The second light-emitting element 170 can be an organic light-emitting diode, and the light-emitting layer 174 can be an organic light-emitting layer.

The light-emitting layer 174 and the second electrode 176 of the second sub-pixel SP2 can be extended into and also be provided in the first sub-pixel SP1. In the first sub-pixel SP1, the light-emitting layer 174 can be separated corresponding to the recessed portion 117a to thereby expose the second connection electrode 164 provided on the side wall of the recessed portion 117a.

On the other hand, in the first sub-pixel SP1, the second electrode 176 may not be separated corresponding to the recessed portion 117a and can be in contact with the exposed second connection electrode 164 on the side wall of the recessed portion 117a. Accordingly, the second electrode 176 can be electrically connected to the second element electrode 154 through the second connection electrode 164.

As such, in the light-emitting diode display device according to the embodiment of the present disclosure, the first light-emitting element 150 of the first sub-pixel SP1 can be configured as the inorganic light-emitting diode, and the second light-emitting element 170 of the second sub-pixel SP2 can be configured as the organic light-emitting diode, thereby improving the luminous efficiency.

Here, the area of the second sub-pixel SP2 provided with the organic light-emitting diode can be larger than the area of the first sub-pixel SP1 provided with the inorganic light-emitting diode, and the aperture ratio of the organic light-emitting diode can be increased. Accordingly, the brightness of the display device can be improved, and the power consumption can be reduced.

Light from the first light-emitting element 150 and the second light-emitting element 170 can be output to the outside through the substrate 110, and the light-emitting diode display device according to the embodiment of the present disclosure can be a bottom emission type display device.

In this case, the first light-emitting element 150 can emit blue light, and the second light-emitting element 170 can emit white light. The white light emitted from the second light-emitting element 170 can pass through the color filter layer 140 to be output as red or green light.

However, embodiments of the present disclosure are not limited thereto. In other embodiments, the light-emitting diode display device according to the embodiment of the present disclosure can be a top emission type display device in which light emitted from the first light-emitting element 150 and the second light-emitting element 170 can be output to the outside through the second electrode 176 on the opposite side to the substrate 110.

Meanwhile, in the light-emitting diode display device according to the embodiment of the present disclosure, the recessed portion 117a can be provided around the first light-emitting element 150 of the first sub-pixel SP1.

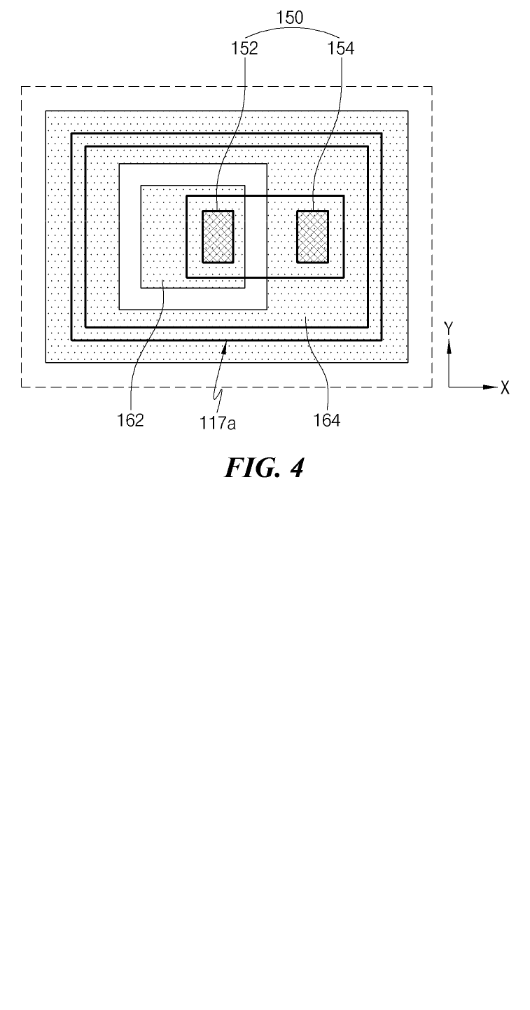

The planar structure of the first sub-pixel SP1 of the light-emitting diode display device according to the embodiment of the present disclosure will be described with reference to FIG. 4.

FIG. 4 is a schematic plan view of a first sub-pixel of a light-emitting diode display device according to the embodiment of the present disclosure.

In FIG. 4, the first light-emitting element 150 can have the first element electrode 152 and the second element electrode 154, and the first connection electrode 162 and the second connection electrode 164 can overlap and be in contact with the first element electrode 152 and the second element electrode 154, respectively.

At this time, the second connection electrode 162 can have a hole corresponding to the first element electrode 152, and the first connection electrode 162 can be spaced apart from the second connection electrode 164 in the hole.

Meanwhile, the recessed portion 117a can be provided in the overcoat layer 117 and overlap the second connection electrode 164. The recessed portion 117a can form a closed-loop. The first connection electrode 162 and the first light-emitting element 150 can be disposed in the recessed portion 117a.

The recessed portion 117a can separate the light-emitting layer 174 and expose the second connection electrode 164 without any additional process. The second electrode 176 can be in contact with the exposed second connection electrode 164. Accordingly, the second electrode 176 can be electrically connected to the second element electrode 154 of the first light-emitting element 150. The second electrode 176 can be connected to both the first light-emitting element 150 and the second light-emitting element 170 and can act as a common electrode.

In addition, light emitted from the first light-emitting element 150 can be reflected by the second electrode 176 provided inside the recessed portion 117a and be output to the outside through the substrate 110, so that the luminous efficiency can be increased.

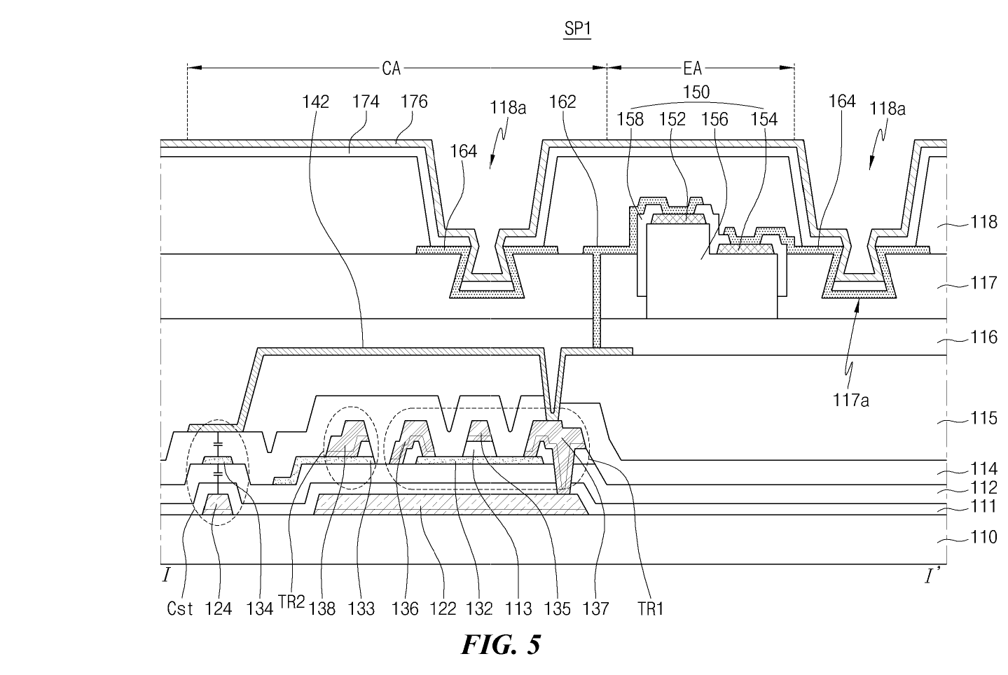

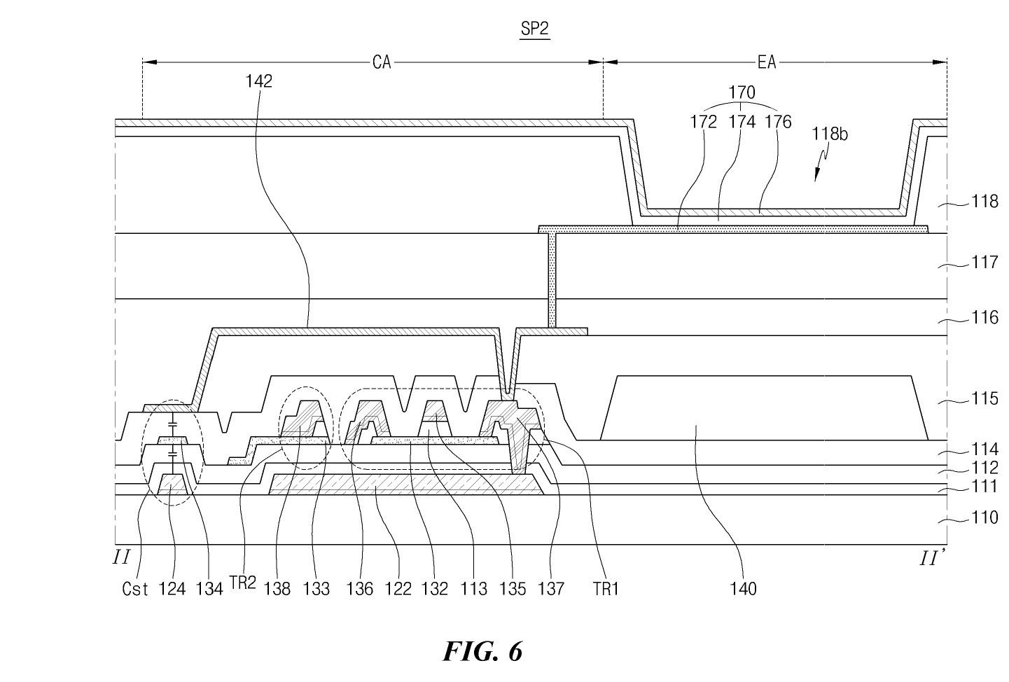

The cross-sectional configurations of the first and second sub-pixels of the light-emitting diode display device according to the embodiment of the present disclosure will be described in detail with reference to FIG. 5 and FIG. 6.

FIG. 5 is a schematic cross-sectional view of a first sub-pixel of a light-emitting diode display device according to the embodiment of the present disclosure and shows a cross-section corresponding to line I-I′ of FIG. 1. FIG. 6 is a schematic cross-sectional view of a second sub-pixel of the light-emitting diode display device according to the embodiment of the present disclosure and shows a cross-section corresponding to line II-II′ of FIG. 1.

In FIG. 5 and FIG. 6, the first sub-pixel SP1 and the second sub-pixel SP2 can be provided over the substrate 110, and each of the first and second sub-pixels SP1 and SP2 can include the emission area EA and the circuit area CA.

The substrate 110 can be a glass substrate or a plastic substrate. For example, polyimide can be used for the plastic substrate, and the plastic substrate can have a stacked structure including at least one polyimide layer and at least one inorganic layer. However, embodiments of the present disclosure are not limited thereto.

A light-shielding layer 122 and a first capacitor electrode 124 can be provided in each circuit area CA over the substrate 110. The light-shielding layer 122 and the first capacitor electrode 124 can be in contact with the substrate 110. The light-shielding layer 122 and the first capacitor electrode 124 can be formed of a conductive material such as metal. The light-shielding layer 122 and the first capacitor electrode 124 can be formed of one or more of: aluminum (Al), copper (Cu), molybdenum (Mo), titanium (Ti), chromium (Cr), nickel (Ni), tungsten (W), and an alloy thereof. For example, the light-shielding layer 122 and the first capacitor electrode 124 can have a double-layered structure including a lower layer of a molybdenum-titanium alloy (MoTi) and an upper layer of copper (Cu), and the upper layer can have a thicker thickness than the lower layer. However, embodiments of the present disclosure are not limited thereto. In other embodiments, the light-shielding layer 122 and the first capacitor electrode 124 can have a single-layered structure or a triple-layered structure.

A first buffer layer 111 and a second buffer layer 112 can be sequentially provided over the light-shielding layer 122 and the first capacitor electrode 124. The first buffer layer 111 and the second buffer layer 112 can be disposed substantially all over the substrate 110. The first buffer layer 111 and the second buffer layer 112 can be formed of an inorganic insulating material, such as silicon oxide (SiOx), silicon nitride (SiNx), or silicon oxynitride (SiON), and can be formed as a single layer or multiple layers. One of the first buffer layer 111 and the second buffer layer 112 can be omitted.

A first active layer 132, a second active layer 133, and a second capacitor electrode 134 can be provided in each circuit area CA over the second buffer layer 112.

The first active layer 132 and the second active layer 133 can overlap the light-shielding layer 122. The light-shielding layer 122 can block light incident on the first active layer 132 and the second active layer 133, and reduce or prevent the first active layer 132 and the second active layer 133 from deteriorating due to the light. However, embodiments of the present disclosure are not limited thereto. In other embodiments, the first active layer 132 can overlap the light-shielding layer 122, and the second active layer 133 can be spaced apart from the light-shielding layer 122 without overlapping.

Meanwhile, the second capacitor electrode 134 can overlap the first capacitor electrode 124 and be spaced apart from the light-shielding layer 122.

The first active layer 132, the second active layer 133, and the second capacitor electrode 134 can be formed of an oxide semiconductor material. However, embodiments of the present disclosure are not limited thereto. In other embodiments, the first active layer 132, the second active layer 133, and the second capacitor electrode 134 can be formed of polycrystalline silicon. In this case, both end portions of each of the first active layer 132 and the second active layer 133 and the whole portion of the second capacitor electrode 134 can be doped with impurities.

A gate insulation layer 113 can be provided over the second buffer layer 112, the first active layer 132, the second active layer 133, and the second capacitor electrode 134. A first gate electrode 135, a first source electrode 136, a first drain electrode 137, and a second source/drain electrode 138 can be provided over the gate insulation layer 113.

The gate insulation layer 113 can be patterned to have substantially the same shape as each of the first gate electrode 135, the first source electrode 136, the first drain electrode 137, and the second source/drain electrode 138. However, embodiments of the present disclosure are not limited thereto. In other embodiments, the gate insulation layer 113 can be disposed substantially all over the substrate 110.

The gate insulation layer 113 can be formed of an inorganic insulating material, such as silicon oxide (SiOx), silicon nitride (SiNx), or silicon oxynitride (SiON), and can be formed as a single layer or multiple layers.

When the first active layer 132 and the second active layer 133 are formed of an oxide semiconductor material, the gate insulation layer 113 can be formed of silicon oxide (SiOx). Alternatively, when the first active layer 132 and the second active layer 133 are formed of polycrystalline silicon, the gate insulation layer 113 can be formed of silicon oxide (SiOx), silicon nitride (SiNx), or silicon oxynitride (SiON).

The first gate electrode 135, the first source electrode 136, and the first drain electrode 137 can overlap the first active layer 132, and the first gate electrode 135 can be disposed between the first source electrode 136 and the first drain electrode 137. Here, the first source electrode 136 and the first drain electrode 137 can be in contact with the first active layer 132. In addition, the first drain electrode 137 can be in contact with the light-shielding layer 122 through a contact hole provided in the first and second buffer layers 111 and 112 and the gate insulation layer 113.

Meanwhile, the second source/drain electrode 138 can overlap the second active layer 133 and be in contact with the second active layer 133. Although not shown in the figures, a second gate electrode can be further provided to overlap the second active layer 133, and a gate insulation layer can be further disposed between the second active layer 133 and the second gate electrode.

The first gate electrode 135, the first source electrode 136, the first drain electrode 137, and the second source/drain electrode 138 can be formed of a conductive material such as metal. The first gate electrode 135, the first source electrode 136, the first drain electrode 137, and the second source/drain electrode 138 can be formed of one or more of: aluminum (Al), copper (Cu), molybdenum (Mo), titanium (Ti), chromium (Cr), nickel (Ni), tungsten (W), and an alloy thereof. For example, the first gate electrode 135, the first source electrode 136, the first drain electrode 137, and the second source/drain electrode 138 can have a double-layered structure including a lower layer of a molybdenum-titanium alloy (MoTi) and an upper layer of copper (Cu), and the upper layer can have a thicker thickness than the lower layer. However, embodiments of the present disclosure are not limited thereto. In other embodiments, the first gate electrode 135, the first source electrode 136, the first drain electrode 137, and the second source/drain electrode 138 can have a single-layered structure or a triple-layered structure.

The first active layer 132, the first gate electrode 135, the first source electrode 136, and the first drain electrode 137 can constitute a first thin film transistor TR1, and the second active layer 133, the gate electrode, and the second source/drain electrode 138 can constitute a second thin film transistor TR2.

The first thin film transistor TR1 can be the driving transistor TR2 of FIG. 1, and the second thin film transistor TR2 can be the switching transistor T1 or the sensing transistor T3 of FIG. 1.

A passivation layer 114 can be provided over the first gate electrode 135, the first source electrode 136, the first drain electrode 137, and the second source/drain electrode 138. The passivation layer 114 can be disposed substantially all over the substrate 110. The passivation layer 114 can be formed of an inorganic insulating material, such as silicon oxide (SiOx), silicon nitride (SiNx), or silicon oxynitride (SiON), and can be formed as a single layer or multiple layers.

Next, the color filter layer 140 can be provided over the passivation layer 114 in the second sub-pixel SP2. The color filter layer 140 can be disposed in the emission area EA of the second sub-pixel SP2 and may not be provided in the first sub-pixel SP1.

When the second sub-pixel SP2 is the red sub-pixel SPr, the color filter layer 140 can be a red color filter, and when the second sub-pixel SP2 is the green sub-pixel SPg, the color filter layer 140 can be a green color filter. Alternatively, when the second sub-pixel SP2 is the white sub-pixel SPw, the color filter layer 140 can be omitted.

The planarization layer 115 can be provided over the passivation layer 114 and the color filter layer 140. The planarization layer 115 can be disposed substantially all over the substrate 110. The planarization layer 115 can be removed to correspond to the first and second capacitor electrodes 124 and 134, thereby exposing a top surface of the passivation layer 114 over the first and second capacitor electrodes 124 and 134.

The planarization layer 115 can be formed of an organic insulating material such as photosensitive acrylic polymer (photo acryl). The planarization layer 115 can eliminate a step difference due to the layers thereunder and can have a substantially flat top surface.

The pixel electrode 142 can be provided over the planarization layer 115 in the circuit area CA. The pixel electrode 142 can be in contact with the first drain electrode 137 through a contact hole provided in the passivation layer 114 and the planarization layer 115.

In addition, the pixel electrode 142 can be in contact with top and side surfaces of the planarization layer 115 and also be in contact with the top surface of the passivation layer 114 exposed over the first and second capacitor electrodes 124 and 134.

The pixel electrode 142 can overlap the first and second capacitor electrodes 124 and 134. The first capacitor electrode 124, the second capacitor electrode 134, and the pixel electrode 142 overlapping each other can constitute the storage capacitor Cst. In this case, the first capacitor electrode 124 and the second capacitor electrode 134 can constitute a first capacitor with the first and second buffer layers 111 and 112 therebetween as a dielectric, and the second capacitor electrode 134 and the pixel electrode 142 can constitute a second capacitor with the passivation layer 114 therebetween as a dielectric. The first and second capacitors can be connected in parallel.

The pixel electrode 142 can be formed of a conductive material such as metal. For example, the pixel electrode 142 can be formed of one or more of: aluminum (Al), copper (Cu), molybdenum (Mo), titanium (Ti), chromium (Cr), nickel (Ni), tungsten (W), and an alloy thereof. Alternatively, the pixel electrode 142 can be formed of a transparent conductive material. For example, the pixel electrode 142 can be formed of indium tin oxide (ITO) or indium zinc oxide (IZO).

The adhesive layer 116 can be provided over the pixel electrode 142. The adhesive layer 116 can be disposed substantially all over the substrate 110. The adhesive layer 116 can have a substantially flat top surface and can be formed of an organic insulating material such as photosensitive acrylic polymer (photo acryl).

The first light-emitting element 150 can be provided over the adhesive layer 116 in the first sub-pixel SP1. The first light-emitting element 150 can be disposed in the emission area EA of the first sub-pixel SP1.

The first light-emitting element 150 can be provided in the form of a micro light-emitting diode chip (micro-LED chip or µLED chip) including an n-electrode, an n-type layer, an active layer, a p-type layer, and a p-electrode. The first light-emitting element 150 can have a lateral chip structure or a flip-chip structure in which the n-electrode and the p-electrode are provided on the same side (for example, a side opposite to a side facing the substrate 100). However, embodiments of the present disclosure are not limited thereto. In other embodiments, the first light-emitting element 150 can have a vertical chip structure in which the n-electrode and the p-electrode are provided on opposite sides, respectively.

The first light-emitting layer 150 can include the first element electrode 152, the second element electrode 154, a semiconductor layer 156, and a protection layer 158. The first element electrode 152 and the second element electrode 154 can be spaced apart from each other over the semiconductor layer 156. The semiconductor layer 156 can include an n-type layer, an active layer, and a p-type layer.

Here, the first element electrode 152 can be a p-electrode, and the second element electrode 154 can be an n-electrode. The first element electrode 152 can be an anode, and the second element electrode 154 can be a cathode.

However, embodiments of the present disclosure are not limited thereto. In other embodiments, the first element electrode 152 can be an n-electrode, and the second element electrode 154 can be a p-electrode. In this case, the first element electrode 152 can be an anode, and the second element electrode 154 can be a cathode.

The protection layer 158 can cover the first element electrode 152, the second element electrode 154, and the semiconductor layer 156 and can partially expose each of the first element electrode 152 and the second element electrode 154. The protection layer 158 can be formed of an inorganic insulating material.

Next, the overcoat layer 117 can be provided over the adhesive layer 116 and the first light-emitting element 150. The overcoat layer 117 can be disposed substantially all over the substrate 110. The overcoat layer 117 can be formed of an organic insulating material such as photosensitive acrylic polymer (photo acryl). The overcoat layer 117 can have a substantially flat top surface.

A thickness of the overcoat layer 117 can be smaller than a thickness of the first light-emitting element 150. The overcoat layer 117 can be in contact with a side surface of the first light-emitting element 150 and expose the first and second element electrodes 152 and 154.

In the first sub-pixel SP1, the overcoat layer 117 can have the recessed portion 117a surrounding at least one side of the first light-emitting element 150 (e.g., a first side surface S1 of the first light-emitting element 150, a second side surface S2 of the first light-emitting element 150). The recessed portion 117a can have a width that becomes narrower as a distance from the substrate 110 increases. The recessed portion 117a can have a top width W1 smaller than a bottom width W2. Accordingly, a side surface of the overcoat layer 117 corresponding to the recessed portion 117a can have a reverse inclination with respect to the substrate 110.

A depth of the recessed portion 117a can be smaller than the thickness of the overcoat layer 117. However, embodiments of the present disclosure are not limited thereto. The depth of the recessed portion 117a can be the same as the thickness of the overcoat layer 117.

The first connection electrode 162, the second connection electrode 164, and the first electrode 172 can be provided over the overcoat layer 117. The first connection electrode 162 and the second connection electrode 164 can be disposed in the first sub-pixel SP1, and the first electrode 172 can be disposed in the second sub-pixel SP2.

In the first sub-pixel SP1, the first connection electrode 162 can overlap and be in contact with the first element electrode 152. In addition, the first connection electrode 162 can be in contact with the pixel electrode 142 through the contact hole provided in the adhesive layer 116 and the overcoat layer 117. Accordingly, the first connection electrode 162 can be electrically connected to the first drain electrode 137 of the first thin film transistor TR1 through the pixel electrode 142, and the first element electrode 152 can be electrically connected to the pixel electrode 142 through the first element electrode 162.

In the first sub-pixel SP1, the second connection electrode 164 can overlap and be in contact with the second element electrode 154. In addition, the second connection electrode 164 can overlap and cover the recessed portion 117a. The second connection electrode 164 can be in contact with the top surface of the overcoat layer 117. The second connection electrode 164 may not be cut off by the recessed portion 117a and can be extended to be provided on the side surface and the bottom surface of the overcoat layer 117 corresponding to the recessed portion 117a.

The second connection electrode 164 can have the hole, and the first connection electrode 162 can be disposed in the hole. Accordingly, the first connection electrode 162 can be spaced apart from the recessed portion 117a and be disposed in the recessed portion 117a.

Meanwhile, in the second sub-pixel SP2, the first electrode 172 can be substantially disposed in the emission area EA and overlap the color filter layer 140. The first electrode 172 can ben in contact with the pixel electrode 142 through the contact hole provided in the adhesive layer 116 and the overcoat layer 117. Accordingly, the first electrode 172 can be electrically connected to the first drain electrode 137 of the first thin film transistor TR1 through the pixel electrode 142.

The first connection electrode 162, the second connection electrode 164, and the first electrode 172 can be formed of a conductive material having relatively high work function. For example, the first connection electrode 162, the second connection electrode 164, and the first electrode 172 can be formed of a transparent conductive material such as indium tin oxide (ITO) or indium zinc oxide (IZO).

The bank layer 118 can be provided over the first connection electrode 162, the second connection electrode 164, and the first electrode 172.

In the first sub-pixel SP1, the bank layer 118 can cover the first light-emitting element 150 and the first connection electrode 162. The bank layer 118 can have the first opening 118a corresponding to the recessed portion 117a. A width W3 of the first opening 118a can be greater than the top width W1 of the recessed portion 117a, and the second connection electrode 164 corresponding to the recessed portion 117a can be exposed through the first opening 118a.

Meanwhile, in the second sub-pixel SP2, the bank layer 118 can have the second opening 118b corresponding to the emission area EA. The bank layer 118 can cover edges of the first electrode 172 and expose a central portion of the first electrode 172 through the second opening 118b.

The bank layer 118 can be formed of an organic insulating material such as photosensitive acrylic polymer (photo acryl).

Next, the light-emitting layer 174 and the second electrode 176 can be sequentially provided over the bank layer 118. The light-emitting layer 174 can be in contact with top and side surfaces of the bank layer 118. The light-emitting layer 174 can also be in contact with the second connection electrode 164 and the first electrode 174 exposed through the first and second openings 118a and 118b, respectively.

Specifically, in the second sub-pixel SP2, the light-emitting layer 174 can be in contact with the first electrode 174 exposed through the second opening 118b.

In the second sub-pixel SP2, the first electrode 172, the light-emitting layer 174, and the second electrode 176 provided in the emission area EA can constitute the second light-emitting element 170. The second light-emitting element 170 can be an organic light-emitting diode, and the light-emitting layer 174 can be an organic light-emitting layer.

The light-emitting layer 174 can be extended into and also be provided in the first sub-pixel SP1. In the first sub-pixel SP1, the light-emitting layer 174 can overlap and cover the first light-emitting element 150 and be in contact with the second connection electrode 164 exposed through the first opening 118a.

Meanwhile, in the first sub-pixel SP1, the light-emitting layer 174 can be separated by the recessed portion 117a. That is, a portion of the light-emitting layer 174 in the recessed portion 117a can be separated from a portion of the light-emitting layer 174 over the overcoat layer 117 except for the recessed portion 117a, thereby exposing the second connection electrode 164 provided on the side wall of the recessed portion 117a.

The light-emitting layer 174 can emit white light and can include at least one hole auxiliary layer, at least one light-emitting material layer, and at least one electron auxiliary layer constituting one light-emitting unit. The hole auxiliary layer can include at least one of a hole injection layer (HIL) and a hole transport layer (HTL). The electron auxiliary layer can include at least one of an electron injection layer (EIL) and an electron transport layer (ETL).

Here, the light-emitting layer 174 can have a stack structure in which two or more light-emitting units emitting different colors are stacked, and a charge generation layer (CGL) can be provided between two or more light-emitting units.

The second electrode 176 of a conductive material with relatively low work function can be provided over the light-emitting layer 174. The second electrode 176 can be disposed substantially all over the substrate 110.

The second electrode 176 can be extended into and also be provided in the first sub-pixel SP1. In the first sub-pixel SP1, the second electrode 176 can overlap and the cover the first light-emitting element 150.

The second electrode 176 may not be separated by the recessed portion 117a and can be in contact with the second connection electrode 164 exposed on the side wall of the recessed portion 117a. Accordingly, the second electrode 176 can be electrically connected to the second element electrode 154 through the second connection electrode 164.

The second electrode 176 can be formed of a conductive material such as metal. For example, the second electrode 176 can be formed of aluminum (Al), magnesium (Mg), silver (Ag), or an alloy thereof. The second electrode 176 can reflect light, and the reflectance of the second electrode 176 can be higher than the reflectance of the first electrode 172.

As such, in the light-emitting diode display device according to the embodiment of the present disclosure, by providing the first light-emitting element 150 of the first sub-pixel SP1 as the inorganic light-emitting diode and the second light-emitting element 170 of the second sub-pixel SP2 as the organic light-emitting diode, the inorganic light-emitting diode and the organic light-emitting diode having the relatively high quantum efficiency can be applied together in one pixel, thereby improving the luminous efficiency.

In this case, the area of the first sub-pixel SP1 provided with the inorganic light-emitting diode can be decreased, and the area of the second sub-pixel SP2 provided with the organic light-emitting diode can be increased, so that the aperture ratio of the organic light-emitting diode can be increased. Accordingly, the brightness of the display device can be improved, thereby increasing the lifetime of the display device. The power consumption can be reduced, and the reliability of a product can be improved.

In addition, by providing the recessed portion 117a around the first light-emitting element 150, the light-emitting layer 174 can be separated without any additional process to expose the second connection electrode 164, and the second electrode 176 can be in contact with the exposed second connection electrode 164. At this time, light emitted from the first light-emitting element 150 can be reflected by the second electrode 176 provided in the recessed portion 117a, thereby further increasing the luminous efficiency.

In the light-emitting diode display device of the present disclosure, by applying the inorganic light-emitting diode and the organic light-emitting diode having the relatively high quantum efficiency together in one pixel, the luminous efficiency can be improved, and the brightness of the display device can be increased, thereby increasing the lifetime of the display device.

Further, the area of the organic light-emitting diode can be increased, thereby improving the aperture ratio. The brightness of the display device can be further improved, so that the lifetime of the display device can be further increased and the reliability of a product can be improved.

Accordingly, the power consumption can be reduced due to the increase in efficiency of the light-emitting diode and the improved lifetime of the light-emitting diode, thereby achieving the low power consumption.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light-emitting diode display device, comprising:
a substrate including a first sub-pixel and a second sub-pixel;
a first light-emitting element provided in the first sub-pixel; and
a second light-emitting element provided in the second sub-pixel,
wherein the second light-emitting element includes a first electrode, a light-emitting layer, and a second electrode, and
wherein the light-emitting layer of the second light-emitting element is further provided in the first sub-pixel and overlaps the first light-emitting element.

2. The light-emitting diode display device of claim 1, wherein the first light-emitting element is disposed between the substrate and the light-emitting layer.

3. The light-emitting diode display device of claim 1, further comprising an overcoat layer between the substrate and the second light-emitting element,
wherein the overcoat layer has a recessed portion surrounding at least one side of the first light-emitting element.

4. The light-emitting diode display device of claim 3, wherein a side wall of the recessed portion has a reverse inclination with respect to the substrate, and a top width of the recessed portion is smaller than a bottom width of the recessed portion.

5. The light-emitting diode display device of claim 3, further comprising a first connection electrode and a second connection electrode between the overcoat layer and the light-emitting layer in the first sub-pixel,
wherein the first connection electrode and the second connection electrode are connected to the first light-emitting element, and
wherein the first connection electrode is spaced apart from the recessed portion, and the second connection electrode overlaps the recessed portion.

6. The light-emitting diode display device of claim 5, wherein the first connection electrode and the second connection electrode include a same material and on a same layer as the first electrode.

7. The light-emitting diode display device of claim 5, wherein the second connection electrode has a hole, and the first connection electrode is disposed in the hole.

8. The light-emitting diode display device of claim 5, wherein the light-emitting layer and the second electrode overlap the second connection electrode, and
wherein the light-emitting layer is separated by the recessed portion to thereby expose the second connection electrode, and the second electrode is in contact with the exposed second connection electrode.

9. The light-emitting diode display device of claim 5, wherein the second connection electrode overlaps the recessed portion from a plan view.

10. The light-emitting diode display device of claim 1, further comprising:
a thin film transistor provided in each of the first and second sub-pixels; and
a pixel electrode connected to the thin film transistor,
wherein the first light-emitting element is disposed between the pixel electrode and the light-emitting layer.

11. The light-emitting diode display device of claim 10, further comprising an adhesive layer between the pixel electrode and the first light-emitting element.

12. The light-emitting diode display device of claim 1, further comprising a color filter layer between the substrate and the first electrode in the second sub-pixel.

13. The light-emitting diode display device of claim 12, wherein a color filter layer is not provided between the substrate and the first electrode in the first sub-pixel.

14. The light-emitting diode display device of claim 1, wherein the first light-emitting element is an inorganic light-emitting diode, and the second light-emitting element is an organic light-emitting diode.

15. The light-emitting diode display device of claim 14, wherein the first light-emitting element emits blue light, and the second light-emitting element emits white light.

16. The light-emitting diode display device of claim 14, wherein an area of the second light-emitting element is larger than an area of the first light-emitting element.
